(19) United States
(12) Patent Application Publication
(10) Pub. No.: US 2007/0284728 A1
(43) Pub. Date: Dec. 13, 2007

(54) Flip-chip bonding structure using multi chip module-deposited substrate

(75) Inventors: Kwang-Seok Seo, Seoul (KR); Sang-Sub Song, Seoul (KR)

Correspondence Address: THOMAS, KAYDEN, HORSTEMEYER & RISLEY, LLP, 600 GALLERIA PARKWAY, STE 1500, ATLANTA, GA, 30339, US

(73) Assignee: Seoul National University Industry Foundation

(21) Appl. No.: 11/450,064

(22) Filed: Jun. 9, 2006

(51) Int. Cl. H01L 23/12; H01L 21/44

(52) U.S. Cl. 257/700; 257/E23.174; 438/613

(57) ABSTRACT

An MCM-D substrate in accordance with the present invention includes a silicon substrate provided with a Si-bump and a ground bump formed thereon, an insulating layer formed on the silicon substrate, a metal layer patterned on the insulating layer, a dielectric layer, a transmission line, a flip-chip bonding bump and a mounted component. The mount component is installed on a top of the Si-bump by a flip-chip bonding bump and the Si-bump prevents a dielectric layer from placing below the flip-chip bonding bump unlike a conventional technology. A ground bump makes an electric contact between a metal formed on a ground and a metal on the dielectric layer through a deep-via free process.

### BACKGROUND OF THE INVENTION

1. Field of the Invention

The present invention relates to a flip-chip bonding technology; and, more particularly, to a flip-chip bonding and an interconnection structure of a transmission line related to a multi chip module-deposited(MCM-D) substrate.

2. Background of the Related Art

Recently, as a result of increasing a request for a bandwidth, a millimeter-wave application such as a short-range wide-area wireless communication has been currently studied together with a lot of interests. However, in order to allow such application to have a practical use commercially, there is necessarily required a commercial packaging technology to allow a millimeter-wave module having a high performance and a compact size with a low cost. The multi chip module-deposited (MCM-D) technology is one of most excellent technologies to satisfy the above requirement by allowing it to access a system-on-package(SOP) utilizing thin film dielectric layers as well as by allowing it to have a high resolution pattern necessarily required for being applied to a millimeter-wave frequency having an ultra short frequency. In addition, the flip-chip interconnection technology has an advantage such as a small parasitic component, a low process cost and a high productivity in comparison with a conventional wire bonding as well as has an advantage in electronic operation of the millimeter-wave by reducing an interconnection length. Therefore, the above-described requirements are achieved by installing a mounted component such as a monolithic millimeter-wave integrated circuit(MMIC) on an MCM-D substrate by using a flip-chip technology. But, there are several issues to be considered while such flip-chip bonding technology is employed.

In order to improve reliability of the flip-chip structure, there is considered issues of a coefficient of the thermal expansion(CTE) matching between the substrate and the chip and of a heat path to remove the heat generated during the operating of the chip. More specifically, the CTE matching between the substrate and the chip is very important since a thermal stress is concentrated on a flip-chip bonding portion. And also, when the flip-chip bonding technology is used in a high frequency region, it is excellent in a transmission characteristic of a transmission line manufactured at the substrate, has a small proximity effect between the substrate and the chip, and allows a parasitic mode incidence generated at a package structure to be suppressed. The substrate is very important since such issues related to the flip-chip bonding technology are related to a substrate characteristic in the flip-chip structure. Currently, an alumina substrate is most widely used for the flip-chip bonding substrate. Since the alumina substrate is a semi-insulating substrate, it is capable of manufacturing a transmission line to have an excellent transmission characteristic, and since the CTE(6 ppm/° C.) of the alumina is similar to the CTE(7 ppm/° C.) of the chip, the flip-chip structure has a very excellent reliability. However, when the alumina is used as the substrate, a proximity effect between the substrate and the chip appears due to a high dielectric constant, i.e., 9.8, of the alumina, and a heat generated during an operation of the chip cannot be effectively removed by a low thermal conductivity(30 W/m° K). And also, since the alumina substrate is a semi-insulating substrate, it is known that the alumina substrate does not prevent the parasitic mode generated at the package structure from being inputted.

In order to effectively suppress a parasitic mode incidence generated at the package structure, a lossy silicon substrate 1 is used for a package substrate. At this time, benzocyclobuten(BCB) 2 is coated on a whole surface of the silicon substrate to remove the problems such as a characteristic deterioration of RF devices generated due to the lossy silicon substrate. A transmission line 3 having an excellent transmission characteristic can be manufactured on the lossy silicon substrate due to the wholly coated BCB and the proximity effect between the substrate and the chip can be reduced due to the low dielectric constant, i.e., approximately 2.6, of the BCB. However, since the CTE(56 ppm/° C.) of the BCB coated on the whole surface of the lossy silicon substrate is very high in comparison with the CTE of the chip, there occurs a CTE mismatching between the substrate and the chip 5, in turn, which causes the reliability of the flip-chip bonding structure to be deteriorated. And also, it is difficult that the heat generated during the chip operation is removed due to low heat conductivity, i.e., 0.02 W/m° K of the BCB.

On the other hand, in the MCM-D substrate, for example a via hole must be formed in a BCB layer to make an electrical contact of metal lines formed with a dielectric layer therebetween. Although such via hole can be easily formed by using a photo-sensitive BCB as the BCB layer, due to the sensitivity to various process parameters the via hole formation of the photo sensitive BCB cannot be reliable. Also although the via hole formation of the dry-type BCB can be implemented through the etching of the BCB, to form the via hole in the thick BCB layer takes a long time as well as the via hole formation process becomes difficult.

### SUMMARY OF THE INVENTION

### Technical Problem

The present invention has been proposed in order to overcome the above-described problems in the related art. It is, therefore, an object of the present invention to provide an MCM-D substrate capable of improving reliability of a flip-chip bonding structure and effectively removing a heat generated during a chip operation by allowing a flip-chip bonding bump to have a coefficient of the thermal expansion(CTE), i.e., 3 ppm/° C.), similar to that of a chip and positioning it at a Si-bump having a high thermal conductivity, i.e., 150 W/m° K.

It is another object of the present invention to provide a multi chip module-deposited(MCM-D) substrate capable of reducing a proximity effect between a substrate and a chip due to a low dielectric constant of a benzocyclobuten(BCB).

It is still another object of the present invention to provide a deep-via free MCM-D substrate capable of easily forming a reliable via hole even in a dry-type BCB as well as in a photo sensitive BCB using a ground bump without forming the via hole required to form a micro-strip type transmission line by not entirely etching a thick BCB.

### Technical Solution

In accordance with an aspect of the present invention, there is provided a multi chip module deposited(MCM-D) substrate, including:

a silicon substrate including a Si-bump and a ground bump formed by being separated from each other by etching the silicon substrate;

an insulating layer formed on the silicon substrate;

a metal layer patterned on the insulating layer; and

at least one dielectric layer formed on the insulating layer or the metal layer, wherein the metal layer is formed on a top surface and a sloping surface of the ground bump, a ground and a top surface of the Si-bump.

In accordance with another aspect of the present, there is provided a method for manufacturing a multi chip module deposited(MCM-D) substrate, including the steps of:

forming a protection layer on a region for a ground bump and a Si-bump at a silicon substrate;

forming the ground bump and the Si-bump by etching the silicon substrate;

forming an insulating layer on the silicon substrate; and

forming a metal layer on the insulating layer and etching the metal layer by performing a patterning, wherein the metal layer is formed on a top surface and a sloping surface of the ground bump, a ground and a top surface of the Si-bump.

### BRIEF DESCRIPTION OF DRAWINGS

The above and other objects and features of the present invention will become apparent from the following description of the preferred embodiments given in conjunction with the accompanying drawings, in which:

FIG. 1 is a cross-sectional view illustrating a flip-chip bonding structure according to a prior art;

FIG. 2 is a cross-sectional view showing a flip-chip bonding structure of a multi chip module deposited(MCM-D) substrate in accordance with an embodiment of the present invention; and

FIGS. 3A to 3O are cross-sectional views describing a process of manufacturing the flip-chip bonding structure employing the MCM-D substrate in accordance with the embodiment of the present invention.

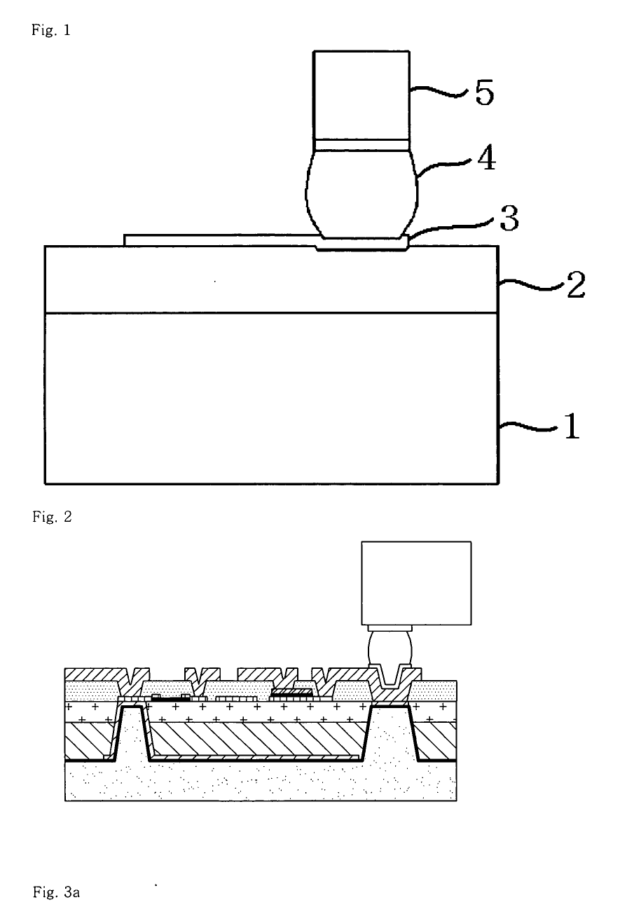

### DETAILED DESCRIPTION OF THE INVENTION

Hereinafter, a preferred embodiment of the present invention will be described in detail with reference to the accompanying drawings.

FIG. 2 is a cross-sectional view showing a flip-chip bonding structure of a multi chip module deposited(MCM-D) substrate in accordance with an embodiment of the present invention. The MCM-D substrate in accordance with a present invention includes a silicon substrate provided with a Si-bump and a ground bump formed thereon, an insulating layer formed on the silicon substrate, a metal layer patterned on the insulating layer, a dielectric layer, a transmission line, a flip-chip bonding bump and a mounted component. The mount component is installed on a top of the Si-bump by a flip-chip bonding bump and the Si-bump prevents a dielectric layer from placing below the flip-chip bonding bump unlike a conventional technology. A ground bump makes an electric contact between a metal formed on a ground and a metal on the dielectric layer through a deep-via free process.

A characteristic of the silicon substrate is that its CTE is 3 ppm/° C. similar to the CTE of the mount component and its thermal conductivity is large, i.e., 150 W/cm. Since the Si-bump is obtained by etching the silicon substrate, a characteristic of the Si-bump is same as that of the silicon substrate. Besides, since the CTEs of the silicon substrate and the Si-bump are comparatively matched with the CTE of the mount component, when the package described above takes into a process of absorbing a heat, the mount component and the Si-bump are expanded at the same rate, in other words, a stress applied to the flip-chip bonding bump is reduced. And also, since the silicon has a thermal conductivity very higher than that of the dielectric material, the Si-bump of the present invention supplies more effective heat path to disperse a heat generated by the mount component. And also, since the conventional silicon substrate has a lossy characteristic, it prevents the parasitic mode from inputting. The transmission line is installed on a dielectric layer. Therefore, the transmission line has an excellent characteristic even on the lossy silicon substrate. That is, although a transmission loss is large when the transmission line is simply installed on a silicon substrate, it becomes a small when the transmission line is installed on the silicon substrate coated with the BCB. And also, a proximity effect is represented by the BCB having a dielectric constant being approximately 2.65. And, although the BCB is used as the dielectric layer in accordance with the present invention, the other materials having a good planarization characteristic and available for coating except for the BCB can be used. The structure and effect of such Si-bump are well described in a non-published U.S. patent application Ser. No. 11/302,635 commonly owned by the present inventors.

In case of a ground bump, a metal layer formed on a ground and a ground bump top surface can be electrically contacted by a metal layer formed on a sloping surface of the ground bump. Herein, the ground means a region of the silicon substrate where each bump is not formed but the metal layer formed. This can be utilized as a contact for a ground metal, for example, thin film micro-strip(TFMS) line. The electric contact by the ground bump overcomes the problems of the prior art by removing the process of etching a deep via hole after a thick BCB layer is formed. The reason of the formation of the sloping surface on the ground bump is to increase the deposition efficiency of the metal layer by easily depositing the metal layer on the sloping surface of the bump. This causes the electric contact to be improved by allowing the metal layer to be deposited sufficiently thick at the sloping surface without an additional depositing process. Meanwhile, the metal layer of the Si-bump sloping surface can be removed by a patterning.

In accordance with the embodiment of the present invention, there is provided a method for manufacturing the MCM-D substrate further improved by forming the ground bump having the above-described advantages at the same time without another additional process in a manufacturing method of the substrate using such Si-bump.

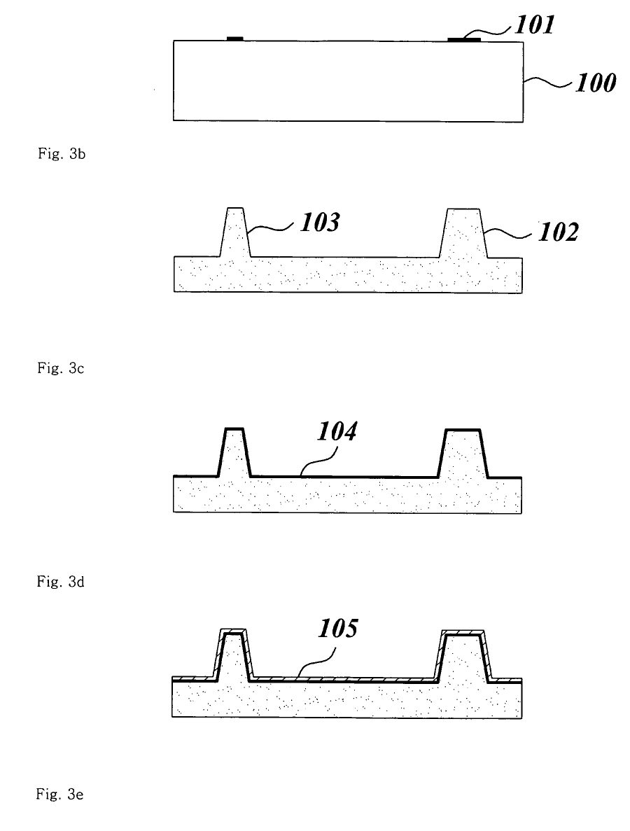

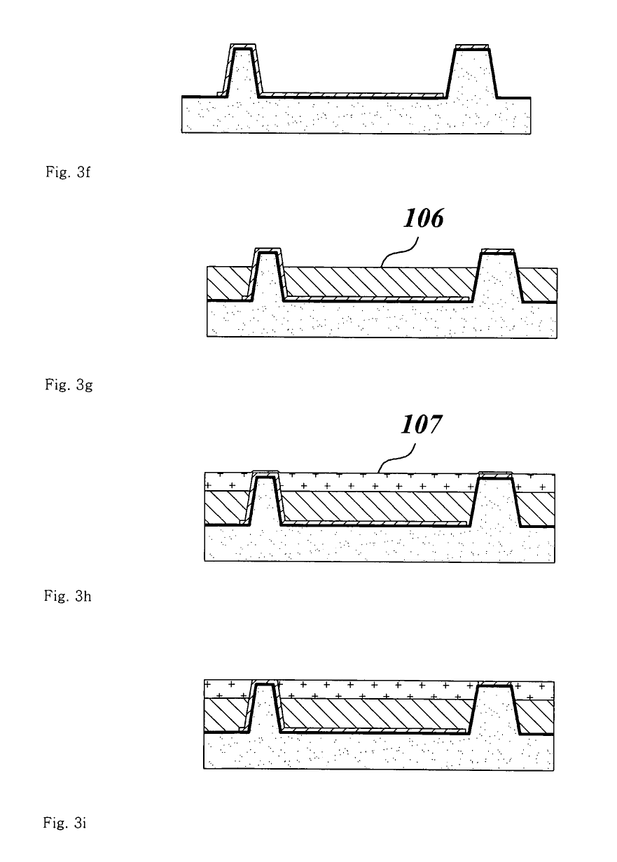

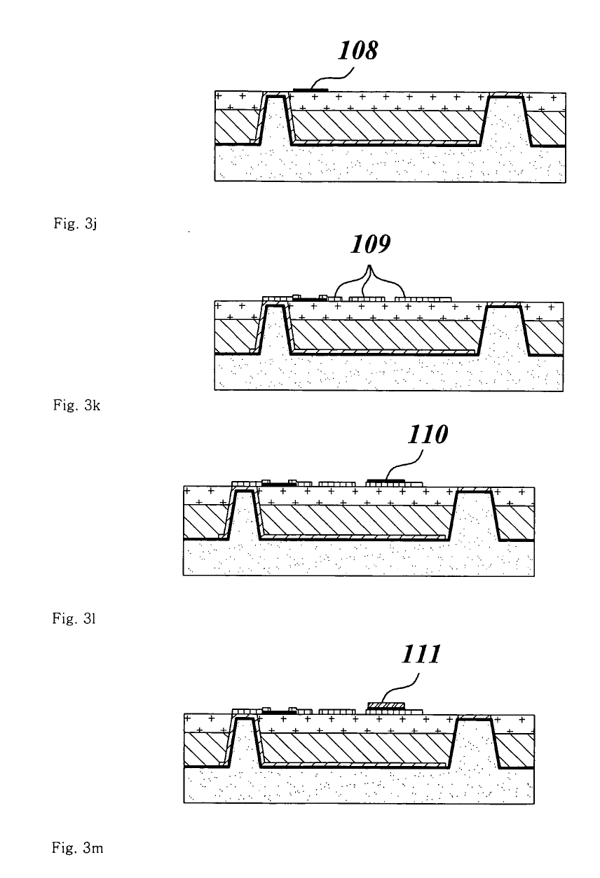

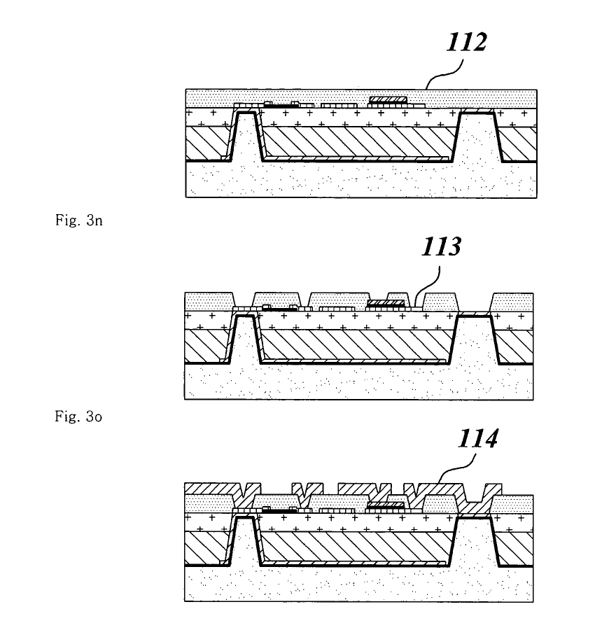

A detailed description for the present invention is shown in FIG. 3A to FIG. 3O.

Referring to FIG. 3A, at first, a protection layer 101 is formed on a lossy silicon substrate 100 and the protection layer 101 is patterned into a predetermined shape. The protection layer 101 is made of SiNx or SiO₂ and its thickness is formed below approximately 1,000 Å. A Si-bump 102 and a ground bump 103 are formed on a region at which the patterned protection layer 101 remains.

Referring to FIG. 3B, after the protection layer 101 is patterned, the lossy silicon substrate 100 is wet etched by a predetermined depth. Since the region at which the protection layer 101 remains are protected from the etching, the Si-bump 102 and the ground bump 103 are formed on the lossy silicon substrate 100. In the embodiment of the present invention, heights of the bumps 102 and 103 are approximately 20 μm. The heights of the bumps 102 and 103 can be formed in a range of 10-100 μm. Side surface of each bump 102 and 103 do not form a right angle with respect to a plane surface, and regions of each bump 102 and 103 become to wide as shown in the drawings by having an inclination of approximately 55° in view of a characteristic of a silicon etching as going to the substrate 100. And also, a ground bump and a silicon bump in such shape can be formed by a dry etching in place of the wet etching. Meanwhile, the region which is not protected by the protection layer 101 forms the ground.

Referring to FIG. 3C, an insulating layer 104 is formed on the lossy silicon substrate 100 formed thereon the bumps 102 and 103. The insulating layer 104 is made of a dielectric such as SiO₂, SiNx or Al₂O₃, and its thickness is ranging from approximately 10-1,000 Å. A DC leakage current can be generated by a characteristic of the lossy silicon substrate 100 through the lossy silicon substrate 100. In order to prevent such DC leakage current, the insulating layer 104 is generated on the silicon substrate 100.

Referring to FIGS. 3D and 3E, a metal layer 105 is formed on the insulating layer 104 and the metal layer 105 is patterned into a predetermined shape. The metal layer 105 can be a metal having a large conductivity such as alumina, gold or copper, and a thickness of the metal layer 105 is below 2 μm. The metal layer 105 formed on a region, on which the bumps 102 and 103 do not exist, plays a role of a ground metal. In case of the metal layer 105 formed on the ground bump 103, since the sloping surface of the ground bump 103 has an angle of approximately 55° not a right angle, the metal layer 105 is formed relatively thick on the sloping surface of the ground bump 103. The metal layer 105 formed on the sloping surface of the ground bump 103 easily makes an electric contact with the metal layer formed on the ground and the dielectric layer by being in contact with the ground metal in place of the metal filled in a conventional via hole through a deep-via free process. More particularly, since the micro-strip line is grounded to a ground metal, such contact can be utilized to ground the ground metal. On the other hand, since to connect the metal on the top surface of the Si-bump 102 to the ground metal by the metal layer 105 formed on the sloping surface of the Si-bump 102 can cause a short circuit, the metal layer formed on the sloping surface of the Si-bump 102 can be removed in the patterning process of the metal layer 105. The wet etching and the dry etching can be used for etching the metal layer.

Referring to FIG. 3F and FIG. 3G, in order to fill the etched region of the silicon substrate 100 after the metal layer 105 is patterned, the dielectric layers 106 and 107 are formed. In the embodiment of the present invention, the BCB is used for the dielectric layer 106, and the dielectric layer 106 is formed by using a spin coating process. Since the Si-bump 102 and the ground bump 103 are very small in diameter, the dielectric layers 106 and 107 become uniform and flat by the spin coating. The BCB layer mainly used as the dielectric layer 106 and 107 for the millimeter-wave module has a very low dielectric loss in a loss tangent of approximately 0.0005, and the dielectric constant is very small, i.e., approximately 2.65. Since the BCB layer has a good planarization characteristic, it does not require for performing an additional planarization process. The BCB layer can be a single layer or a multiple layers. For example, if the heights of each bump 102 and 103 including the metal layer 105 and the insulating layer 104 are 20 μm, after the first dielectric layer 106 is formed at a thickness of 15 μm, the second dielectric layer 107 is formed at a thickness of 5 μm to achieve further excellent planarization characteristics. Through the procedure shown above, the top surface of dielectric layer 106 should cover slightly the metal layer 105 on the top surface of each bump 102 and 103.

Referring to FIG. 3H, the metal layer 105 of each bump top surface is exposed by etching the BCB dielectric layer on the top surface of each bump 102 and 103 using a mask. Such etching is performed by a dry etching based on an RIE by using SF₆/O₂ or CF₄/O₂. In this case, since the fluorine based etchant can etch the ground bump 102 and the Si-bump 103 when the BCB dielectric on the top surface of the each bump to play a role of the protection layer. At this time, the electrical contact with the ground metal can be achieved by exposing the metal layer 105 of the top surface of the ground bump 103 simultaneously.

Referring to FIGS. 3I to 3O, a passive device such as a resistor or a capacitor and a transmission line are formed on the dielectric layers 106 and 107 and after a dielectric layer 112 is formed thereon a transmission line 114 is formed on the dielectric layers. The transmission line 114 transmits the signal from the mounted component to another circuit. In one embodiment, NiCr resistor(TFR) 108 is formed on the dielectric layers 106 and 107, and the metal(Au) layer 109 playing roles of a bottom metal of the MIM capacitor and a transmission line is formed. Thereafter, the dielectric layer 110 of the MIM capacitor is formed, the top electrode 111 of the MIM capacitor is formed, and the BCB layer is spin coated as the dielectric layer 112. An etching is performed on the spin coated BCB layer for the via hole 113, and finally the transmission line(Au) 114 is formed in a thickness of approximately 2 μm. In this case, since the etching of the via hole 113 of the dielectric layer 112 is etched by a very small thickness, there is no problem in a process.

Referring to FIG. 2, finally the flip-chip bonding bump is formed on the transmission line of the Si-bump. In the flip-chip bonding bump, a conventional solder bump material is used. The mounted component is installed on the flip-chip bonding bump.

The MCM-D substrate in accordance with the embodiment of the present invention is capable of reducing a proximity effect between the substrate and the chip by a small dielectric constant of the BCB. At the same time, the MCM-D substrate in accordance with the embodiment of the present invention is capable of improving reliability of a flip-chip bonding structure and effectively removing a heat generated during a chip operation by allowing a flip-chip bonding bump to have a coefficient of the thermal expansion(CTE), i.e., 3 ppm/° C.), similar to that of a chip and positioning it at a Si-bump having a high thermal conductivity, i.e., 150 W/m° K.

And also, the MCM-D substrate is easily manufactured by supplied a method for manufacturing the MCM-D substrate capable of forming an electric contact between a metal formed on a ground and a metal formed on a dielectric layer by the ground bump without etching a via hole for a dielectric layer such as a BCB.

Although certain example methods, apparatus and articles of manufacture have been described herein, the scope of coverage of this invention is not limited thereto. On the contrary, this patent covers all methods, apparatus and articles of manufacture fairly falling within the scope of the appended claims either literally or under the doctrine of equivalents.

What is claimed is:

1. A multi chip module deposited(MCM-D) substrate, comprising:
a silicon substrate including a Si-bump and a ground bump formed by being separated from each other by etching the silicon substrate;
an insulating layer formed on the silicon substrate;
a metal layer patterned on the insulating layer; and
at least one dielectric layer formed on the insulating layer or the metal layer, wherein the metal layer is formed on a top surface and a sloping surface of the ground bump, a ground and a top surface of the Si-bump.

2. The MCM-D substrate as recited in claim 1, wherein the insulating layer is made of a material selected from SiO₂, SiN, and Al₂O₃.

3. The MCM-D substrate as recited in claim 2, wherein a thickness of the insulating layer is ranging from 10 Å to 1,000 Å.

4. The MCM-D substrate as recited in claim 1, wherein the metal layer is a material having a high conductivity.

5. The MCM-D substrate as recited in claim 4, wherein a thickness of the metal layer is 2 μm.

6. The MCM-D substrate as recited in claim 1, wherein the Si-bump and the ground bump are formed by using a wet etching.

7. The MCM-D substrate as recited in claim 1, wherein each sloping surface of the Si-bump and the ground bump has an angle of approximately 55° with respect to a plane surface, and top surfaces of the Si-bump and the ground bump are smaller than bottom surfaces.

8. A method for manufacturing a multi chip module deposited(MCM-D) substrate, comprising the steps of:
Forming a protection layer on a region for a ground bump and a Si-bump at a silicon substrate;
forming the ground bump and the Si-bump by etching the silicon substrate;
forming an insulating layer on the silicon substrate; and
forming a metal layer on the insulating layer and etching the metal layer by performing a patterning, wherein the metal layer is formed on a top surface and a sloping surface of the ground bump, a ground and a top surface of the Si-bump.

9. The method as recited in claim 8, wherein the insulating layer is made of a material selected from SiO₂, SiNₓ and Al₂O₃.

10. The method as recited in claim 8, wherein a thickness of the insulating layer is ranging from 10 Å to 1,000 Å.

11. The method as recited in claim 8, wherein the metal layer is a material having a high conductivity.

12. The method as recited in claim 11, wherein a thickness of the metal layer is 2 μm.

13. The method as recited in claim 8, wherein the Si-bump and the ground bump are formed by using a wet etching.

14. The method as recited in claim 8, wherein each sloping surface of the Si-bump and the ground bump has an angle of approximately 55° with respect to a plane surface, and top surfaces of the Si-bump and the ground bump are smaller than bottom surfaces.
